(19) United States
(12) Patent Application Publication
(10) Pub. No.: US 2016/0313795 A1
(43) Pub. Date: Oct. 27, 2016

(54) ELECTRONIC DEVICE

(71) Applicant: PANASONIC INTELLECTUAL PROPERTY MANAGEMENT CO., LTD., Osaka-shi (JP)

(72) Inventor: Fumio MURAMATSU, Kyoto (JP)

(21) Appl. No.: 15/103,405

(22) PCT Filed: Oct. 28, 2014
(86) PCT No.: PCT/JP2014/005451

§ 371 Date: Jun. 10, 2016

(30) Foreign Application Priority Data
Dec. 18, 2013 (JP) 2013-260829

(51) Int. Cl. G06F 3/01; B60K 35/00; G06F 3/0354

(52) U.S. Cl. CPC G06F 3/016; G06F 3/03547; B60K 35/00; B60K 2350/1028; B60K 2350/965

(57) ABSTRACT

An electronic device 100 according to an embodiment includes a panel 210 to be touched by a user; a vibration transmitting section 230 disposed at an interval from the panel 210; a vibrating section 300 to vibrate the vibration transmitting section 230; and an elastic member 400 elastically supporting the panel 210 and the vibration transmitting section 230.

### TECHNICAL FIELD

The present disclosure relates to an electronic device which generates vibration in accordance with a touch operation by a user.

### BACKGROUND ART

Electronic devices including a touch panel have come into practical use. Through touch panel manipulation, however, it is difficult for the user to appreciate a feel of the input manipulation, and thus the user may inadvertently make unintended touch inputs. With a view to improving the manipulability of touch inputs, techniques are known for giving a haptic sensation to the user by vibrating the touch panel. By applying a voltage to a vibrating section which is provided on a touch panel, a vibration is generated on the touch panel, thus allowing the user to experience a haptic sensation (see, for example, Patent Document 1). From the haptic sensation, the user is able to know whether an input to the electronic device has been completed through touch panel manipulation, whereby stable inputting is realized.

### CITATION LIST

### Patent Literature

[Patent Document 1] Japanese Laid-Open Patent Publication No. 4-199416

### SUMMARY

### Technical Problem

The present disclosure provides an electronic device which is able to stably present vibrations to a user in accordance with touch operations.

### Solution to Problem

An electronic device according to an embodiment of the present disclosure includes: a panel to be touched by a user; a vibration transmitting section disposed at an interval from the panel; a vibrating section to vibrate the vibration transmitting section; and an elastic member elastically supporting the panel and the vibration transmitting section.

### Advantageous Effects

In one embodiment of the present disclosure, there is provided an electronic device which, even in the case of a highly rigid panel, produces a sufficient vibration amplitude at a low frequency (e.g. around 100 Hz). In one embodiment of the present disclosure, there is provided an electronic device which reduces discrepancies in haptic sensation that are associated with different touched positions on a touch operation plane.

### BRIEF DESCRIPTION OF DRAWINGS

FIG. 1 A diagram showing an electronic device according to Embodiment 1.

FIG. 2 A diagram showing a touch panel unit according to Embodiment 1.

FIG. 3 (a) to (d) are diagrams describing flexural vibration that is caused in a diaphragm by a piezoelectric element according to Embodiment 1.

FIGS. 4 (a) and (b) are diagrams describing vibrations of a touch panel unit according to Embodiment 1.

FIG. 5 A diagram showing a touch panel unit according to Embodiment 1.

FIG. 6 A diagram showing positions on a diaphragm at which piezoelectric elements and weight pieces are mounted according to Embodiment 2.

FIG. 7 A diagram showing how a weight piece may be mounted on a diaphragm according to Embodiment 2.

FIG. 8 A diagram showing positions on a diaphragm at which piezoelectric elements and weight pieces are mounted according to Embodiment 2.

FIG. 9 A diagram showing a diaphragm according to Embodiment 3.

FIG. 10 A diagram showing a touch panel unit.

### DESCRIPTION OF EMBODIMENTS

Embodiments will now be described in detail, referring to the drawings. Note however that unnecessarily detailed descriptions may be omitted. For example, detailed descriptions on what is well known in the art or redundant descriptions on what is substantially the same constitution may be omitted. This is to avoid lengthy description, and facilitate the understanding of those skilled in the art.

The accompanying drawings and the following description, which are provided by the present inventors so that those skilled in the art can sufficiently understand the present disclosure, are not intended to limit the scope of claims.

First, problems associated with an electronic device which gives a haptic sensation to a user by vibrating a touch panel will be described.

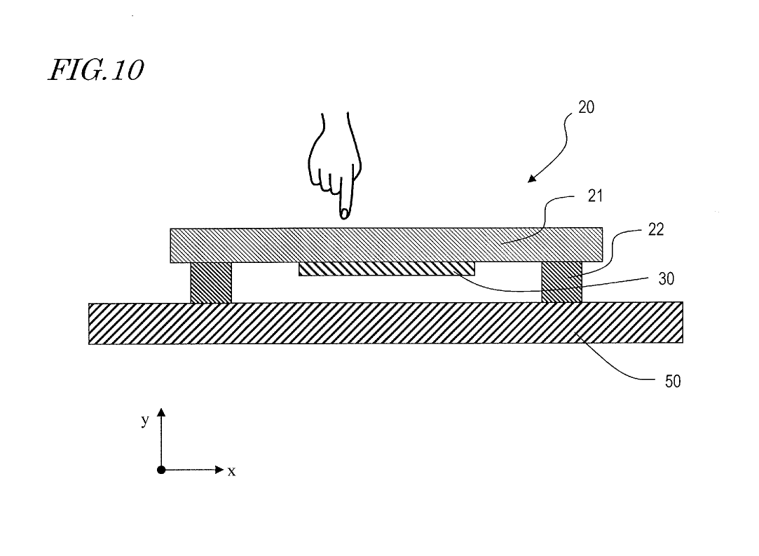

FIG. 10 is a diagram schematically showing a touch panel unit 20. As shown in FIG. 10, a vibrating section 30 to induce vibration of the touch panel 21 is attached to the touch panel 21. The vibrating section 30 is a piezoelectric element, for example. Although the vibrating section 30 is usually mounted on a face of the touch panel 21 that will not be touched by the user, the vibrating section 30 may alternatively be mounted on a face that the user will be touching. The touch panel 21 is supported by fixture portions 22, the fixture portions 22 being fixed to a base 50. The method of fixing the touch panel 21 may be arbitrary, such as screwing or adhesive bonding.

As a voltage is applied to the vibrating section 30 attached to the touch panel 21 so as to cause the touch panel to vibrate, the touch panel unit 20 is able to give a haptic sensation to the user. Thus, from the haptic sensation, the user is able to know whether or not an input to the electronic device has been completed through touch panel manipulation, whereby stable inputting is realized.

In some cases, however, the construction of the touch panel unit 20 shown in FIG. 10 may not be able to present a haptic sensation of a sufficient intensity to the user. The reasons are as follows.

In order to induce substantial vibration in the touch panel 21 with vibration of the vibrating section 30, it would be efficient to utilize a resonance phenomenon. Generally speaking a touch operation plane of the touch panel 21 has a planar shape; however, from the standpoints of ease of use, aesthetic design, or the like, the touch panel 21 may also be shaped to present a curved surface. Example shapes may be those in which the central portion of the touch panel 21 is dented or rises toward the user's touch surface relative to the ends. Moreover, the touch panel 21 may have some ornamental members mounted thereon. In such cases, the touch panel 21 has an improved rigidity, thus resulting in a higher resonant frequency of flexural vibration than that of a touch panel 21 of a planar shape that is made in substantially the same dimensions and same material.

Moreover, the touch panel 21 is a member that will be touched by the user. From safety standpoints, the touch panel 21 is expected not to break up and scatter when a person collides against it in an unpredictable accident or the like. Thus, the touch panel 21 has a certain thickness or greater. When having a large thickness, the touch panel 21 attains an improved rigidity, and its resonant frequency of flexural vibration becomes higher than that of a touch panel 21 with a small thickness that is made in substantially the same dimensions and same material.

If the touch panel 21 has a high vibration frequency, the vibration may feel so sharp as to be unpleasant to the user, feel like an alarm, or otherwise disliked. Moreover, a person is unlikely to perceive any vibration of a certain frequency or greater. For use with haptic sensation presentation, it may be preferable that the vibration of the touch panel 21 is around 100 Hz. Unlike that of a planar shape, a touch panel 21 that is shaped to present a curved surface (such as a flexed shape) may have a resonant frequency of flexural vibration which is several times the frequency of the former, thus making it difficult to efficiently utilize the resonance phenomenon.

If the resonance phenomenon cannot be utilized, then, a multitude of vibrating sections 30 might be attached to the touch panel 21 to ensure intense vibration at around 100 Hz. However, there exists a thin film for touch-detecting purposes attached on the rear face of the touch panel 21, upon which no vibrating sections 30 can be attached. This makes it difficult to attach a multitude of vibrating sections 30 on the touch panel 21. The reason why vibrating sections 30 cannot be attached on the film for touch-detecting purposes is that a high voltage of several dozen volts to be applied to the vibrating sections 30 may lead to misdetections of touched positions on the touch panel 21, or that vibrations of the vibrating sections 30 may not adequately propagate to the panel surface even if piezoelectric elements are attached on the thin and soft film. In other words, it is difficult for a highly-rigid touch panel 21 to attain sufficient vibration amplitude at a frequency as low as around 100 Hz. Moreover, in the case where piezoelectric elements are used, there is an additional problem in that stronger or weaker vibrations may result depending on the place of the touch panel 21 that is touched by the user, because according to natural principles the touch panel 21 undergoes flexural vibration.

In one embodiment of the present disclosure, there is provided an electronic device which provides sufficient vibration amplitude at a low frequency (around 100 Hz) even if its touch panel is highly rigid. In one embodiment of the present disclosure, there is provided an electronic device which reduces discrepancies in haptic sensation that are associated with different touched positions on a touch operation plane.

### Embodiment 1

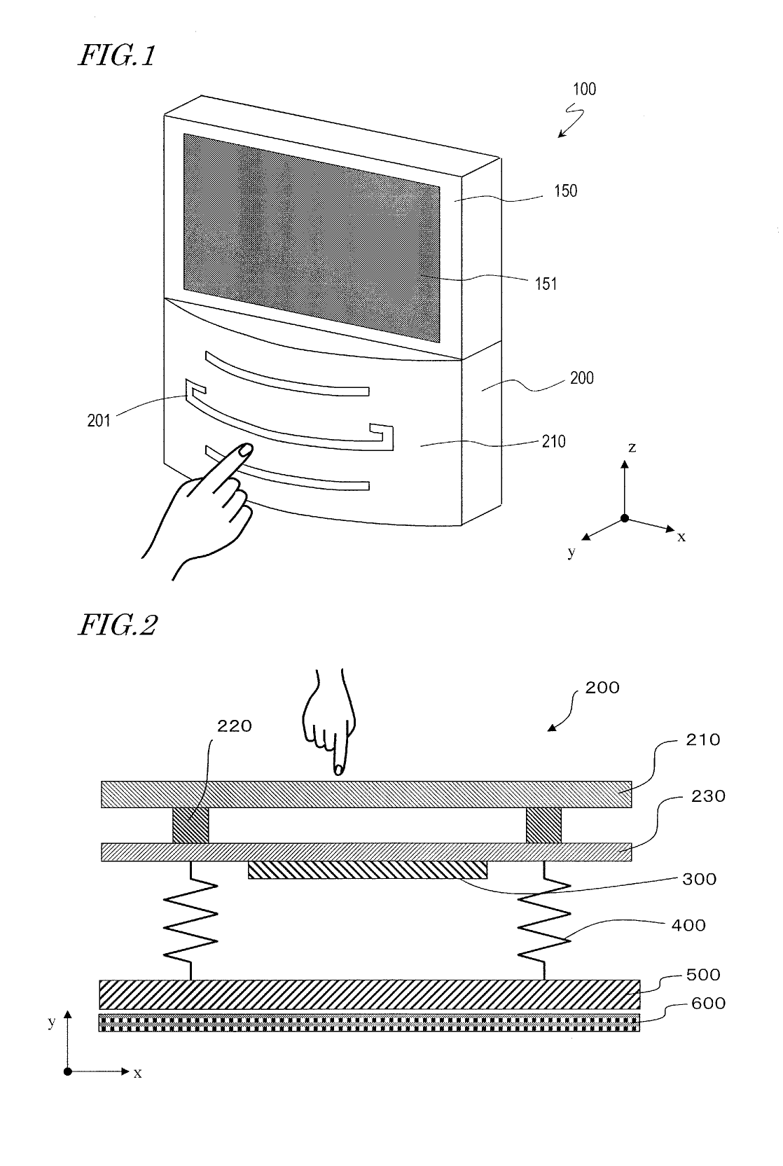

Hereinafter, Embodiment 1 will be described with reference to FIGS. 1 to 4.

[1-1. Construction]

FIG. 1 is a perspective view showing the appearance of an electronic device 100 according to Embodiment 1. The electronic device 100 is a device which can be touch-manipulated by a user, e.g., a car navigation system, a smartphone, or a pad-type computer.

FIG. 1 shows a car navigation system as an example of the electronic device 100. The electronic device 100 shown in FIG. 1 includes a display unit 150 and a touch panel unit 200.

In an image displaying region 151 of the display unit 150, image information, e.g., a map, is mainly displayed. The touch panel unit 200 is an interface which accepts various commands from the user to the electronic device 100. In the case where the touch panel unit 200 includes a display device, manipulation acceptors such as various buttons will be displayed on the touch panel unit 200, and the user will touch on the indicated display acceptors in order to manipulate the electronic device 100. Note that the touch panel unit 200 may lack a display device. Moreover, the display unit 150 may be a touch display unit that includes a touch panel to accept touch operations by the user, in which case the user will be able to render touch operations on both the display unit 150 and the touch panel unit 200.

In the display unit 150 and in the touch panel unit 200, physical buttons may be partially or entirely omitted in order to broaden the image displaying region 151, improve interface freedom, or improve on the aesthetic design. On the other hand, a car navigation system may be manipulated while an automobile is being driven, in which case one may not be able to gaze at the manipulating hands or the manipulation results. In order to provide feedback to the user that a manipulation has been accepted even in such cases, the electronic device 100 has a feedback function through haptic sensation based on panel vibration. Although it is the touch panel unit 200 that possesses the feedback function through haptic sensation based on vibration, the display unit 150 may also possess a feedback function through haptic sensation based on vibration.

In the example of FIG. 1, the touch operation plane of the touch panel 210 is shaped so as to present a curved surface. For example, the touch panel 210 is shaped so that its central portion is dented or rises toward the user's touch operation plane relative to the end shapes.

Moreover, for an improved aesthetic design, an ornament 201 may be provided on the touch panel 210 of the touch panel unit 200. In the case where the ornament 201 has a contoured shape, e.g., a protruding shape, the user may be able to utilize the ornament 201 as a reference position (e.g., a home position) in making touch operations.

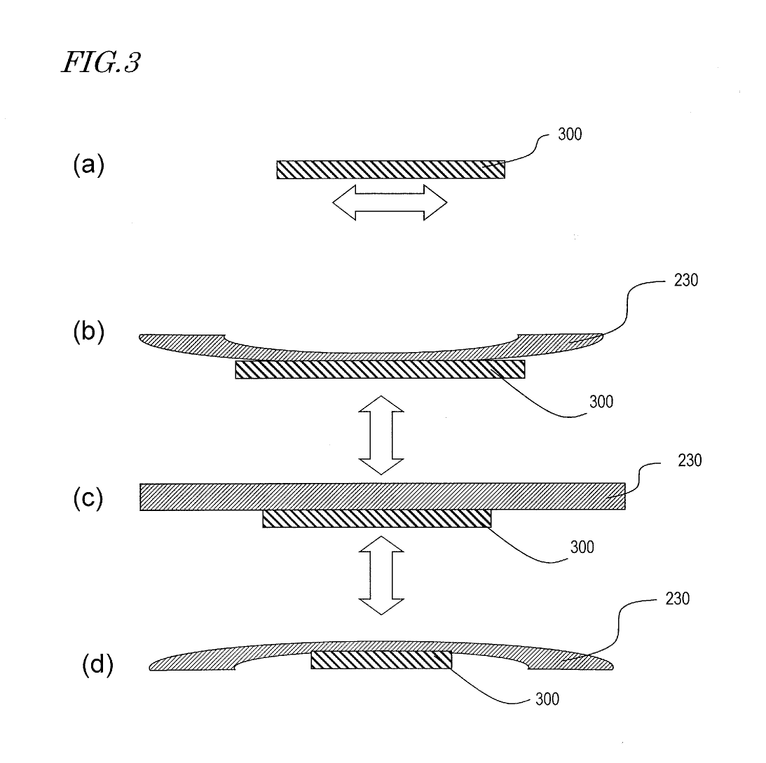

FIG. 2 schematically shows a construction of the touch panel unit 200 according to Embodiment 1.

The touch panel unit 200 includes the touch panel 210, support portions 220, a vibration transmitting section 230, a vibrating section 300, elastic pieces 400, a base 500, and a control section 600.

The touch panel 210 is a panel which is touched by the user to manipulate the touch panel unit 200, or provides feedback to the user by presenting a haptic sensation which is in accordance with the manipulation. Although the example of FIG. 2 illustrates a flat-shaped touch panel 210 for ease of understanding, the touch panel 210 may alternatively be shaped to present a curved surface as has been mentioned earlier.

In this example, the vibration transmitting section 230 is a diaphragm, which is disposed on the opposite side of the touch panel 210 from the side to be touched by the user, at an interval from the touch panel 210. The diaphragm 230 is coupled to the touch panel 210 via the support portions 220. The touch panel 210 and the diaphragm 230 are not of a construction such that they are completely integral, as they would be in the case of being adhesively bonded over the entire surface. In this example, a space is created between the touch panel 210 and the diaphragm 230. The material of the diaphragm 230 may be aluminum or an iron-based metal, a resin-type material, or the like, and a material with a low rigidity to allow it to curve under an external force is to be used. As the method of coupling between the support portions 220, the diaphragm 230, and the touch panel 210, screwing or adhesive bonding is used, but any other method may be used. The touch panel 210 and the support portions 220 may be formed as an integral piece, or the diaphragm 230 and the support portions 220 may be formed as an integral piece.

The vibrating section 300 is mounted on the diaphragm 230. The vibrating section 300 is an actuator that induces flexural vibration in the diaphragm 230. The vibrating section 300 may be a piezoelectric element or a rotary vibration motor, for example. Installation of the vibrating section 300 to the diaphragm 230 may be achieved with the use of an adhesive, a double-coated adhesive tape, or by screwing, etc. Although the vibrating section 300 is to be mounted on the opposite face of the diaphragm 230 from the touch panel 210 as shown in FIG. 2, it may instead be mounted on the face that is proximate to the touch panel 210.

The elastic pieces 400 are mounted between the diaphragm 230 and the base 500. The elastic pieces 400 are connected to the opposite side of the diaphragm 230 from the touch panel 210, to elastically support the touch panel 210, the support portions 220, the diaphragm 230, and the vibrating section 300. The elastic pieces 400 are members that bear the masses of the touch panel 210, the support portions 220, the diaphragm 230, and the vibrating section 300, to generate vibration of a so-called spring-mass system. Since it is intended that flexural vibration of the vibrating section 300 induces spring oscillation in the elastic pieces 400, the positions at which to mount the elastic pieces 400 are not limited to between the diaphragm 203 and the base 500. The elastic pieces 400 may be any members that have elasticity, e.g., rubber washers; alternatively, they may also be springs or the like.

The base 500 is a housing of the electronic device 100 in which component elements of the touch panel unit 200 are to be accommodated. The base 500 is coupled to and supports the elastic pieces 400. An example of the base 500 is the housing of a car navigation system. Note that the base 500 does not need to be a component element of the electronic device 100, but may be an external member on which the electronic device 100 is to be mounted. For example, the base 500 may be a member of a vehicle body in which the car navigation system is to be installed.

The control section 600 is a control circuit to control the operation of the touch panel unit 200, and performs various controls and determinations. The control section 600 includes a microcomputer and a memory, for example, such that the microcomputer operates on the basis of a computer program which is read from the memory. The control section 600 may be included in the touch panel unit 200, or provided in a device which is external to the touch panel unit 200 so as to externally control the operation of the touch panel unit 200.

[1-2. Operation]

An operation of the touch panel unit 200 as above will be described in details below.

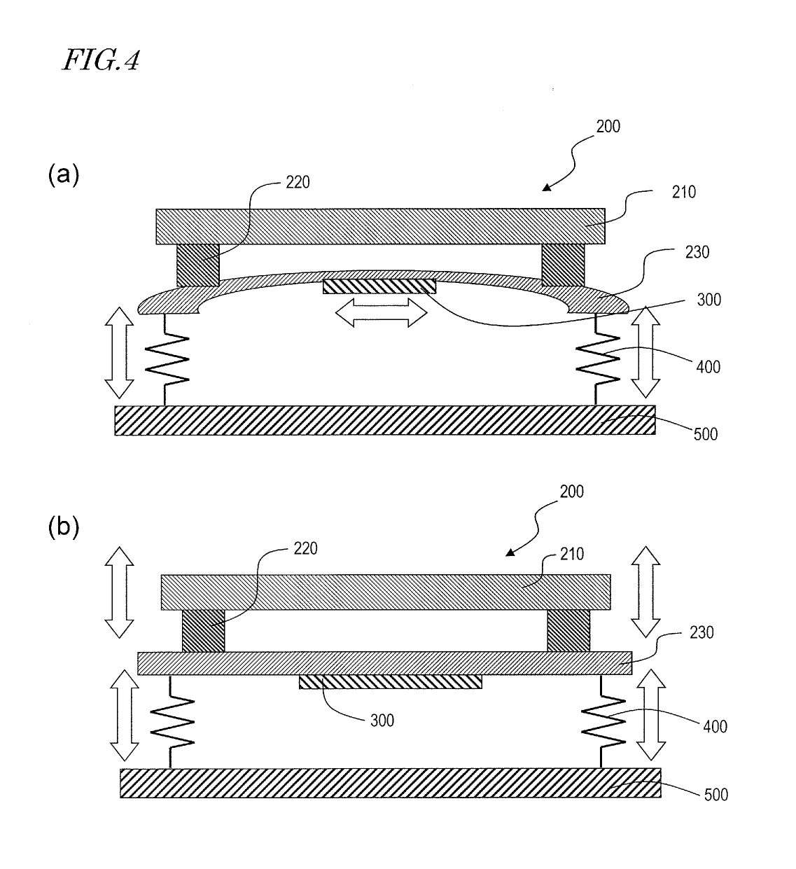

FIG. 3(a) to FIG. 3(d) are diagrams describing how the diaphragm 230 may vibrate in the case where a piezoelectric element is used as an exemplary vibrating section 300. Hereinafter, when illustrating manners of vibration in the figures, a vibration which is above the actual vibration amplitude may occasionally be illustrated for ease of understanding. A piezoelectric element 300 is an electromechanical transducer which expands in one direction with a voltage application between its electrodes (not shown), and contracts under a voltage whose positive or negative polarity is inverted (FIG. 3(a)).

In a construction where the piezoelectric element 300 is attached on the diaphragm 230, when the piezoelectric element 300 is not expanded or contracted, the touch panel maintains its original shape (e.g., a flat shape) (FIG. 3(c)). When the piezoelectric element 300 expands, the diaphragm 230 becomes more dented than its original shape (FIG. 3(b)). When the piezoelectric element 300 contracts, the diaphragm 230 becomes more protruding than its original shape (FIG. 3(d)). When a sine-wave voltage is applied between the electrodes of the piezoelectric element 300, for example, the piezoelectric element 300 undergoes repetitive expansion and contraction. As the piezoelectric element 300 repeats expansion and contraction, flexural vibration is induced in the diaphragm 230 (FIG. 3(b) to FIG. 3(d)).

The magnitude of the voltage to be applied between the electrode of the piezoelectric element 300 and the amount of expansion and contraction of the piezoelectric element 300 are in proportion, and also the amount of expansion and contraction of the piezoelectric element 300 and the amplitude of flexural vibration of the diaphragm 230 are in proportion. Therefore, by adjusting the magnitude of the voltage to be applied to the piezoelectric element 300, it is possible to adjust the vibration amplitude of the diaphragm 230.

FIG. 4 shows how vibration may propagate to the user with the touch panel unit 200. A construction for realizing a feedback function through haptic sensation to propagate vibration to the user will be described below.

The touch panel 210 detects the presence or absence of a user touch, the touched position, the number of touching fingers, the motion of the touching finger(s), and so on. Based on the information of the user's touch operation as detected by the touch panel 210, the control section 600 generates a driving instruction to drive the vibrating section 300, and outputs it to the vibrating section 300. The vibrating section 300 vibrates in accordance with the driving instruction, and this vibration propagates to the touch panel, whereby a haptic sensation is presented to the user that is touching the touch panel.

As has been described with reference to FIG. 3, when a sine-wave voltage is applied between the electrodes of the piezoelectric element 300, the piezoelectric element 300 undergoes expansion and contraction. With the expansion and contraction of the piezoelectric element 300, flexural vibration is induced in the diaphragm 230 (FIG. 4(a)). The diaphragm 230 is disposed with a gap from the touch panel 210. Therefore, rigidity of the touch panel 210 does not restrain flexural vibration, and the diaphragm 230 is allowed to flex with a large vibration amplitude. Moreover, since the diaphragm 230 is in the interior of the electronic device 100, it permits more design freedom, e.g., being made into a planar shape or reduced in thickness, than does the touch panel 210. As a result, it is easy to create a design that sets the resonant frequency of the diaphragm 230 to a desired frequency, e.g. around 100 Hz. For example, the resonant frequency of the diaphragm 230 is set between 50 Hz and 200 Hz. More desirably, the resonant frequency is set between 80 Hz and 150 Hz. The reason why around 100 Hz is exemplified as a desired frequency is that, while the frequencies that are perceptible to humans are 300 Hz or less, the haptic sensation may turn out painful or be perceived as if an alarm at any frequency above 200 Hz. On the other hand, vibration of any frequency that is far below 100 Hz, e.g., vibration of less than 50 Hz, is unlikely to be communicated to humans. By causing resonance in the diaphragm 230, the diaphragm 230 undergoes flexural vibration with a large amplitude. This flexural vibration propagates to the elastic pieces 400 that are coupled to the diaphragm 230, thereby vibrating the elastic pieces 400 (FIG. 4(a)). At this time, the touch panel 210 supported by the elastic pieces 400 will also vibrate along with the elastic pieces 400, whereby the vibration is communicated to the user.

The elastic pieces 400 bear the masses of the touch panel 210, the support portions 220, the diaphragm 230, and the piezoelectric element 300, thus establishing a so-called spring-mass system. By appropriately designing the masses of the component elements that are supported by the elastic pieces 400 and the spring moduli of the elastic pieces 400, the resonant frequency of this spring-mass system can also be set to a desired frequency (e.g. around 100 Hz). In other words, the resonant frequency of the diaphragm 230 and the resonant frequency of the spring-mass system vibration can be equally set around 100 Hz.

As described earlier, in the touch panel unit 200 of the present embodiment, the diaphragm 230 is disposed with a gap from the touch panel 210. As a result, even if the touch panel 210 is highly rigid, flexural vibration of the diaphragm 230 is not restrained and the diaphragm 230 is allowed to flex with a large vibration amplitude.

Moreover, by utilizing resonance of the flexural vibration and resonance of the spring-mass system, and equalizing their frequencies, it becomes possible to efficiently induce vibration in the touch panel 210. It is desirable that the intensity of the vibration to be induced in the touch panel 210 exceeds 2.5 G as translated into acceleration. Note that 2.5 G defines an intensity that allows the vibration to be perceived even when the touch panel 210 is touched in an automobile during travel.

Moreover, the touch panel 210 affects vibration only as a mass, while its shape and rigidity do not affect vibration. Thus, even when shaped so as to have a high rigidity, the touch panel 210 can still present a sufficient haptic sensation.

Furthermore, since the touch panel 210 is subject to the vibration of the spring-mass system and uniformly vibrates in the up-down direction as shown in FIG. 4(a) and FIG. 4(b), the intensity of vibration on the touch operation plane of the touch panel 210 can be made essentially uniform, thereby reducing discrepancies in haptic sensation that are associated with different touched positions on the touch operation plane.

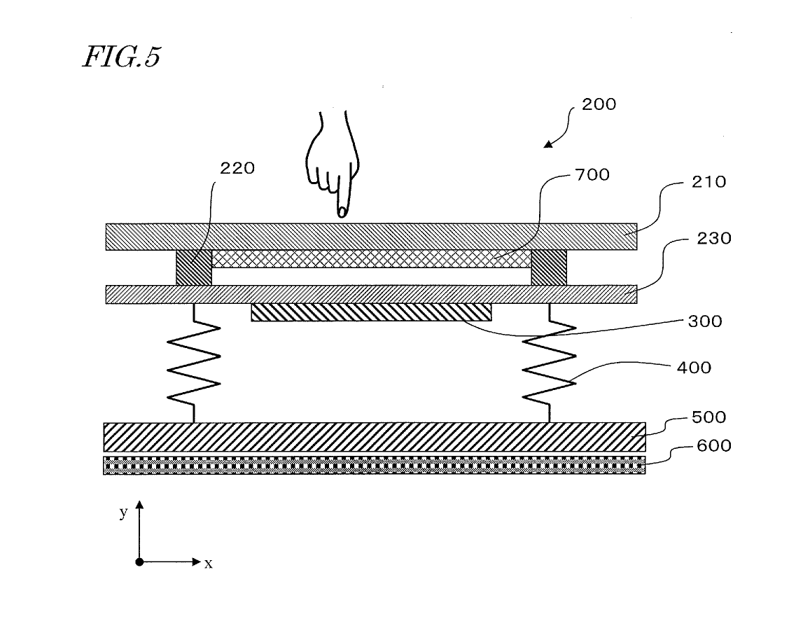

Note that, as shown in FIG. 5, the touch panel unit 200 may include a display device 700 which displays an image. The display device 700 is to be provided on the opposite face of the touch panel 210 from the touch operation plane, for example. In this case, too, the diaphragm 230 is disposed with a gap from the display device 700. Therefore, even if the display device 700 is highly rigid, flexural vibration of the diaphragm 230 is not restrained, and the diaphragm 230 is allowed to flex with a large vibration amplitude. Moreover, this makes it easy to set the resonant frequency of the diaphragm 230 to a desired frequency (e.g. around 100 Hz).

Note that the touch panel 210 and the display device 700 may be formed as an integral piece. For example, the touch panel 210 may be an in-cell type touch panel where the touch panel function is integrated inside the liquid crystal panel, an on-cell type touch panel where the touch panel function is integrated on the surface of a liquid crystal panel, or the like. Moreover, the touch panel 210 may be a touch-sensored display panel that is shaped to present a curved surface, e.g., a curved display, or a touch-sensored display panel that is capable of deformation, e.g., a flexible display. In these cases, too, the diaphragm 230 is disposed with a gap from the touch panel 210, so that flexural vibration of the diaphragm 230 is not restrained, and the diaphragm 230 is allowed to flex with a large vibration amplitude. Moreover, this makes it easy to set the resonant frequency of the diaphragm 230 to a desired frequency (e.g. around 100 Hz).

### Embodiment 2

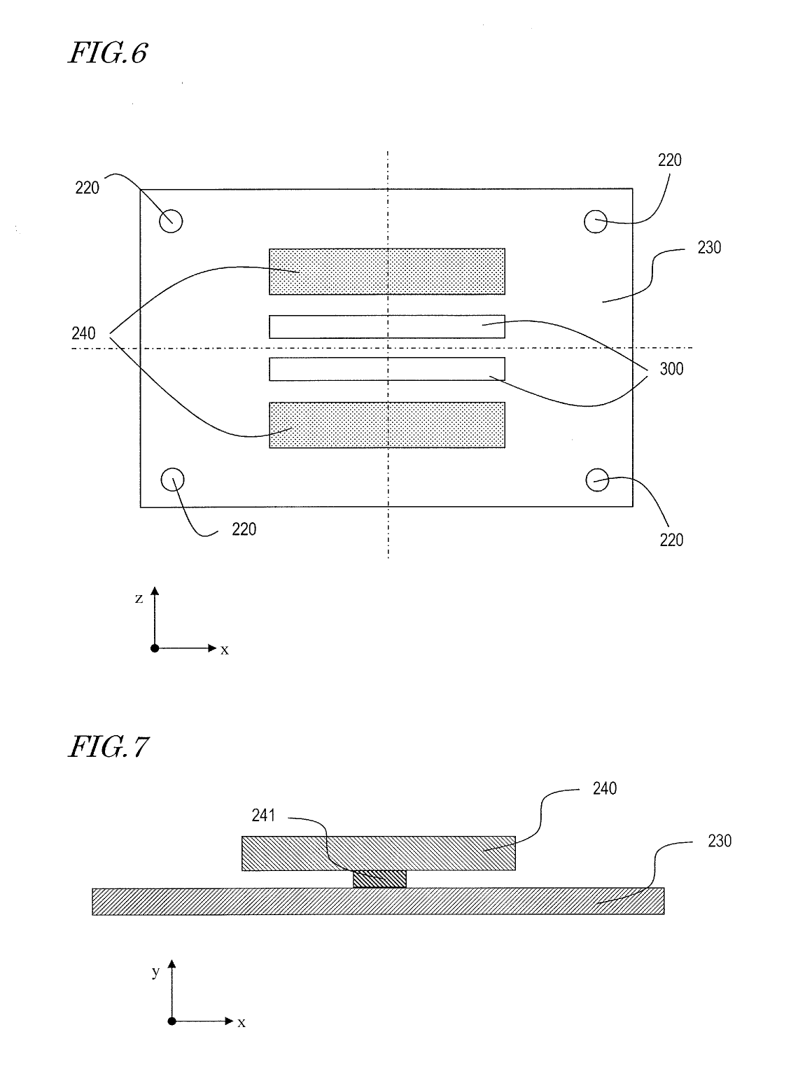

Next, with reference to FIG. 6 to FIG. 8, an electronic device 100 according to Embodiment 2 will be described. FIG. 6 is a plan view schematically showing a diaphragm 230 of the electronic device 100 according to Embodiment 2. Supports 220 for providing support to the touch panel 210 are formed on the diaphragm 230. Moreover, weight pieces 240 and piezoelectric elements 300 are mounted on the diaphragm 230. The diaphragm 230 has a shape which leads to low rigidity, so that, for example, the 0^{th} mode resonance of flexure is around 100 Hz. For example, the diaphragm 230 has a substantially planar shape with minimum protrusions or the like, with a small plate thickness.

The support portions 220 are members that connect the diaphragm 230 and the touch panel 210. The support portions 220 of the diaphragm 230 may be apertures, for example, and by way of threaded holes formed at the support portions 220 on the touch panel 210 side, the diaphragm 230 and the touch panel 210 may be screwed together. The positions of the support portions 220 to be connected to the touch panel 210 define nodes of the vibration of the diaphragm 230. There exist many such vibration modes, e.g., 0^{th} order, 1^{st} order, and 2_{nd} order, where lower-order modes correspond to lower frequencies. A diaphragm 230 of a size which is intended for a generic car navigation system tends to exceed 100 Hz even at the 0^{th} mode. Given the positions of the support portions 220 defining the nodes, and the central vicinity of the diaphragm 230 along the longer side defining an antinode, in order to decrease the 0^{th} mode resonant frequency of this flexural vibration to around 100 Hz, the support portions 220 may need to be provided as much outward on the diaphragm 230 as possible.

The weight pieces 240 are members for increasing the mass of the spring-mass system to adjust the resonant frequency to around 100 Hz. Since the resonant frequency of the spring-mass system is expressed by eq. (2.1), the resonant frequency can be decreased by introducing an increased mass with the weight pieces 240. Examples of the material of the weight pieces 240 include iron-based materials and brass; however, any other metal or resin-type material may also be used.

$$\begin{matrix}[ math . 1 ] & \\ f = \frac{1}{2 π} \sqrt{\frac{k}{m}} \\ f \text{:} resonant frequency [ Hz ] , \\ k \text{:} spring modulus [ N / m ] , \\ m \text{:} mass [ kg ] & eq . ( 2.1 )\end{matrix}$$

The piezoelectric elements 300 are vibration sources which induce flexural vibration in the diaphragm 230. The piezoelectric elements 300 are in positions that are closer to the antinode than to the nodes of the vibration of the diaphragm 230. In this example, the piezoelectric elements 300 are in positions that are closer to the center, than to the ends, of the diaphragm 230. For example, the piezoelectric elements 300 may be attached in the central vicinity of the diaphragm 230. The reasons are as follows.

Regarding resonance of any flexural vibration occurring in the diaphragm 230, the lowest frequency happens in a so-called 0^{th} mode vibration, with its antinode defined at the center along the longer side and nodes defined at the positions of the support portions 220, which does not exhibit any vibration distribution along the shorter side. In order to ensure a greater 0^{th} mode amplitude, it is desirable for the piezoelectric elements 300 to be mounted in the center along the longer side of the diaphragm 230, i.e., at the antinode position of the 0^{th} mode vibration. Along the shorter side, too, the piezoelectric elements 300 are to be mounted in the central vicinity, where vibration is easier to occur than at the upper side and the lower side because of not being restrained by the support portions 220. For example, if two piezoelectric elements 300 are to be mounted as shown in FIG. 6, they may be mounted in the essential center of the diaphragm 230.

Next, with reference to FIG. 7, an exemplary shape of a weight piece 240 will be described. Each weight piece 240 is a member for decreasing the resonant frequency of the spring-mass system to around 100 Hz. A support portion 241 is formed on the weight piece 240, and, as the support portion 241 is connected to the diaphragm 230, the weight piece 240 and the diaphragm 230 become coupled. The area in which the support portion 241 is in contact with the diaphragm 230 is smaller than an area occupied by the weight piece 240 at the diaphragm 230 side.

Moreover, the weight pieces 240 are in positions that are closer to the antinode than to the nodes of the vibration of the diaphragm 230. In this example, the weight pieces 240 is disposed in positions that are closer to the center, than to the ends, of the diaphragm 230. For example, the weight pieces 240 may be mounted in the central vicinity along the longer side of the diaphragm 230.

In this example, in order not to allow the rigidity of the diaphragm 230 to increase, the area of contact between each weight piece 240 and the diaphragm 230 is kept small. The reasons are as follows.

If the entire surface of each weight piece 240 is directly mounted on the diaphragm 230, i.e., not by way of the support portion 241, the diaphragm 230 will increase in rigidity, and the resonant frequency of flexural vibration will be much greater than 100 Hz, thus hindering an efficient use of resonance. Therefore, in order to prevent an increase in rigidity of the diaphragm 230 while allowing the weight pieces 240 to introduce an increased mass in the spring-mass system, it is necessary that the weight pieces 240 be mounted in places where they do not hinder flexural vibration of the diaphragm 230. In order to prevent hindrance of vibration of the diaphragm 230, the weight pieces 240 are disposed in the antinode position of vibration, and their areas of contact with the diaphragm 230 are kept as small as possible. Note that the method of mounting the support portions 241 on the diaphragm 230 may be arbitrary; for example, screwing or adhesive bonding may be used. Moreover, the weight pieces 240 and the support portions 241 may be separate members which may be fixed together by any arbitrary method, e.g., screwing or adhesive bonding.

By attaching the piezoelectric elements 300 in the central vicinity of the diaphragm 230 as shown in FIG. 6 and FIG. 7 and optimizing the positions at which the weight pieces 240 are mounted, more intense vibration can be induced in the touch panel 210.

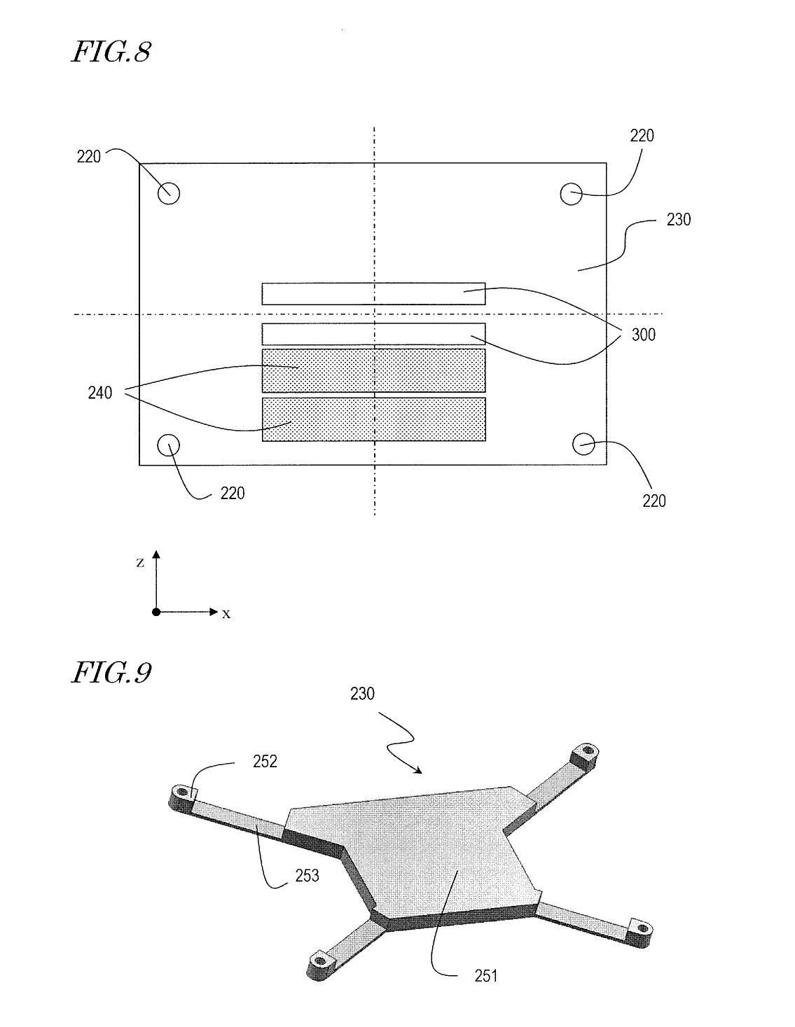

FIG. 8 shows another example of positions on the diaphragm 230 to attach the weight pieces 240. The support portions 220 and the piezoelectric elements 300 are similar to those in the example of FIG. 6.

In the example of FIG. 8, the weight pieces 240 are disposed in a vicinity where an increase in the vibration amplitude of the touch panel 210 is desired. The reasons are as follows.

As has been described with reference to FIG. 4, the touch panel 210 vibrates essentially uniformly across its entirety. However, when there is an extreme inequality in the weight distribution of the touch panel 210 for reasons of aesthetic design or the like, for example, vibration of the touch panel 210 will be non-uniform from position to position. Even in such cases, uniformity in vibration amplitude of the touch panel 210 can be ensured by adjusting the positions on the diaphragm 230 at which to mount the weight pieces 240. Specifically, by allowing the weight pieces 240 to be disposed in a place where an increase in the vibration amplitude of the touch panel 210 is desired, the inertial force is increased, and so is the amplitude. For example, to attain an improved vibration amplitude in the lower portion of the touch panel 210, the weight pieces 240 may be mounted closer to the lower side of the diaphragm 230, as shown in FIG. 8.

By offsetting the positions at which to mount the weight pieces 240 away from the center as shown in FIG. 8, it becomes possible to enhance vibration of the touch panel 210 at places closer to where the weight pieces 240 have been shifted.

### Embodiment 3

Next, with reference to FIG. 9, an electronic device 100 according to Embodiment 3 will be described. FIG. 9 is a perspective view schematically showing a diaphragm 230 of the electronic device 100 of Embodiment 3.

In Embodiments 1 and 2, the vibration transmitting section 230 is described as a diaphragm; in the present embodiment, the vibration transmitting section 230 includes weight pieces 251, support portions 252, and arms 253. In the present embodiment, the piezoelectric elements 300 are attached to the arms 253. Although the material of the vibration transmitting section 230 is an iron-based metal or aluminum, for example, any other metal or resin-type material may also be used.

The weight pieces 251, which define places where weight adjustments are made so that the spring-mass system has a resonant frequency of around 100 Hz, are heavier than the arms 253. Masses of the weight pieces 251 are adjusted mainly by increasing or decreasing their thickness, whereby the resonant frequency of the spring-mass system is set around 100 Hz. Since the weight pieces 251 are thick and highly rigid, flexural vibration hardly occurs in the weight pieces 251 at around 100 Hz.

Via the support portions 220 of the touch panel 210, the support portions 252 couple the vibration transmitting section 230 and the touch panel 210 together. Apertures are made in the support portions 252, and screwing is performed by way of threaded holes formed at the support portions 220 on the touch panel 210; however, other methods of coupling may also be employed.

The arms 253 are fixed to the support portions 252, and support the weight pieces 251. The arms 253 couple the weight pieces 251 and the support portions 252 together, and define places where a flexural resonance around 100 Hz is to be caused in the vibration transmitting section 230. By ensuring that the arms 253 are both thin and narrow, flexural vibration can be caused at a frequency as low as around 100 Hz. Each piezoelectric element 300 is provided on an arm 253 so that at least a portion thereof overlaps the arm 253. As the piezoelectric elements 300 undergo expansion and contraction, flexural vibration at a frequency as low as around 100 Hz can be caused in the arms 253.

By constructing the vibration transmitting section 230 as shown in FIG. 9, the resonant frequency of flexural vibration of the vibration transmitting section 230 and the resonant frequency of the spring-mass system can both be set around 100 Hz, without separately using any members such as the weight pieces 240 (FIG. 6 to FIG. 8); as a result, more intense vibration can be induced in the touch panel 210. Effects similar to those described in Embodiments 1 and 2 above are obtained by using the vibration transmitting section 230 according to the present embodiment.

### Other Embodiments

In the above, Embodiments 1 to 3 have been described as an example of the technique disclosed in the present application. However, the technique of the present disclosure is not limited thereto, but is also applicable to other embodiments in which changes, substitutions, additions, omissions, etc., are made as necessary. Different ones of the elements described in Embodiments 1 to 3 above may be combined together to obtain a new embodiment.

Other embodiments will be illustrated hereinbelow.

Although the above embodiments are directed to a car navigation system as an example of an electronic device, the electronic device is not limited thereto. For example, it may be any electronic device that includes a touch panel, e.g., an information terminal device of a tablet type, a mobile phone, a PDA, a game machine, or an ATM. Moreover, the electronic device may be a pointing device such as a mouse. The electronic device may also be a touch pad.

Although the above embodiments illustrate “around 100 Hz” as an example resonant frequency of flexural vibration of the vibration transmitting section and of the spring-mass system, it may be any other frequency.

Although the above embodiments illustrate piezoelectric elements as vibrating sections, this is not a limitation. Electrostatic force-based actuators, VCMs, vibration motors, or the like may also be used. Moreover, transparent piezoelectric members in the form of thin films may be formed on the vibration transmitting member by sputtering or other methods, so as to be used as vibrating sections.

Although the above embodiments illustrate flexural vibration as an example type of vibration, it may be any other vibration.

Although a haptic sensation is presented by generating vibration in the above-described embodiment, the technique of the present disclosure is not limited thereto. Other than vibration, haptic sensations may be presented by other methods, e.g., as a variation of friction associated with static electricity, a skin stimulation with an electric current, and a variation of the screen shape using liquid. In addition to presenting a haptic sensation, screen display, sounds, light, heat, etc., may be used in combination as necessary.

Note that the vibration operation control for an electronic device described above may be implemented by means of hardware or software. A program implementing such a control operation is stored, for example, in an internal memory of a microcomputer, or a ROM. Such a computer program may be installed onto the electronic device from a storage medium (an optical disc, a semiconductor memory, etc.) on which the computer program is recorded, or may be downloaded via a telecommunication lines such as the Internet.

(Summary)

Thus, as described above, an electronic device 100 according to an embodiment of the present disclosure includes: a panel 210 to be touched by a user; a vibration transmitting section 230 disposed at an interval from the panel 210; a vibrating section 300 to vibrate the vibration transmitting section 230; and an elastic member 400 elastically supporting the panel 210 and the vibration transmitting section 230.

For example, the electronic device 100 may further include a base 500 supporting the elastic member 400.

For example, vibration of the vibration transmitting section 230 may propagate to the elastic member 400 to vibrate the elastic member 400, and cause the panel 210 supported by the elastic member 400 to vibrate.

For example, the resonant frequency of the vibration transmitting section 230 and the resonant frequency of spring-mass system vibration may be equal.

For example, the resonant frequency of the vibration transmitting section 230 may be 50 Hz to 200 Hz.

For example, at an interval from the panel 210, the vibration transmitting section 230 may be disposed on the opposite side of the panel 210 from a side to be touched by the user; and the elastic member 400 may support the panel 210 and the vibration transmitting section 230 at the opposite side of the vibration transmitting section 230 from the panel 210.

For example, the vibrating section 300 may be a piezoelectric element.

For example, the vibrating section 300 may be at a position closer to a central portion, than to ends, of the vibration transmitting section 230.

For example, the vibrating section 300 may be at a position closer to an antinode, than to nodes, of vibration of the vibration transmitting section 230.

For example, a weight piece 240 may be disposed at a position closer to a central portion, than to ends, of the vibration transmitting section 230.

For example, a weight piece 240 may be disposed in a position closer to an antinode, than to nodes, of vibration of the vibration transmitting section 230.

For example, the weight piece 240 may be in contact with the vibration transmitting section 230 in an area which is smaller than an area occupied by the weight piece 240 at the vibration transmitting section 230 side.

For example, the resonant frequency of spring-mass system vibration may be adjusted by the mass of the weight piece 240.

For example, the vibration transmitting section 230 may include: a weight piece 251; a support portion 252 coupling the panel 210 and the vibration transmitting section 230 together; and an arm 253 being fixed on the support portion 252 and supporting the weight piece 251.

For example, the vibrating section 300 may be disposed on the arm 253.

For example, the panel 210 may be shaped to present a curved surface.

For example, the electronic device 100 may be a touch panel 210 unit of a car navigation system.

For example, the electronic device 100 may further include a display section to display an image.

For example, the panel 210 may be an in-cell type touch panel.

For example, the panel 210 may be an on-cell type touch panel.

For example, the electronic device 100 may be a car navigation system.

Embodiments have been described above as an illustration of the technique of the present disclosure. The accompanying drawings and the detailed description are provided for this purpose. Thus, elements appearing in the accompanying drawings and the detailed description include not only those that are essential to solving the technical problems set forth herein, but also those that are not essential to solving the technical problems but are merely used to illustrate the technique disclosed herein. Therefore, those non-essential elements should not immediately be taken as being essential for the reason that they appear in the accompanying drawings and/or in the detailed description.

The embodiments above are for illustrating the technique disclosed herein, and various changes, substitutions, additions, omissions, etc., can be made without departing from the scope defined by the claims and the equivalents thereof.

### INDUSTRIAL APPLICABILITY

The technique according to the present disclosure is especially useful in the technological fields directed to electronic devices that generate vibrations in accordance with touch operations by a user.

### REFERENCE SIGNS LIST

100 electronic device
150 display unit
151 image displaying region
200 touch panel unit
201 ornament
210 touch panel
220, 241, 252 support portion
230 vibration transmitting section
240, 251 weight piece
253 arm
300 vibrating section
400 elastic piece
500 base
600 control section
700 display device

1. An electronic device comprising:
a touch panel;
a vibration transmitting section coupled to the touch panel at an interval therefrom;
a vibrating section to vibrate the vibration transmitting section; and
an elastic member supporting the vibration transmitting section and capable of vibrating responsive to vibration of the vibration transmitting section,
wherein the touch panel being supported by the elastic member by way of the vibration transmitting section.

2. The electronic device of claim 1, further comprising a base supporting the elastic member.

3. The electronic device of claim 1, wherein vibration of the vibration transmitting section propagates to the elastic member to vibrate the elastic member, and causes the touch panel supported by the elastic member to vibrate.

4. The electronic device of claim 1, wherein a resonant frequency of the vibration transmitting section and a resonant frequency of spring-mass system vibration are equal.

5. The electronic device of claim 1, wherein a resonant frequency of the vibration transmitting section is 50 Hz to 200 Hz.

6. The electronic device of claim 1, wherein,
at an interval from the touch panel, the vibration transmitting section is disposed on an opposite side of the touch panel from a side thereof to be touched; and
the elastic member supports the vibration transmitting section at an opposite side of the vibration transmitting section from the touch panel.

7. The electronic device of claim 1, wherein the vibrating section is a piezoelectric element.

8. The electronic device of claim 1, wherein the vibrating section is disposed at a position closer to a central portion, than to ends, of the vibration transmitting section.

9. The electronic device of claim 1, wherein the vibrating section is disposed at a position closer to an antinode, than to nodes, of vibration of the vibration transmitting section.

10. The electronic device of claim 1, wherein a weight piece is disposed at a position closer to a central portion, than to ends, of the vibration transmitting section.

11. The electronic device of claim 1, wherein a weight piece is disposed in a position closer to an antinode, than to nodes, of vibration of the vibration transmitting section.

12. The electronic device of claim 10, wherein the weight piece is in contact with the vibration transmitting section in an area which is smaller than an area occupied by the weight piece at the vibration transmitting section side.

13. The electronic device of claim 10, wherein a resonant frequency of spring-mass system vibration is adjusted by the mass of the weight piece.

14. The electronic device of claim 1, wherein,
the vibration transmitting section comprises:
a weight piece;
a support portion coupling the touch panel and the vibration transmitting section together; and
an arm being fixed on the support portion and supporting the weight piece.

15. The electronic device of claim 14, wherein the vibrating section is disposed on the arm.

16. The electronic device of claim 1, wherein the touch panel is shaped to present a curved surface.

17. (canceled)

18. The electronic device of claim 1, further comprising a display section to display an image.

19.-20. (canceled)

21. The electronic device of claim 18, wherein the electronic device is a car navigation system.

22. The electronic device of claim 1, wherein the vibration transmitting section undergoes flexural vibration responsive to vibration of the vibrating section, and the elastic member undergoes spring oscillation responsive to flexural vibration of the vibration transmitting section.
